(19) United States
(12) Patent Application Publication
(10) Pub. No.: US 2008/0212467 A1
(43) Pub. Date: Sep. 4, 2008

(54) APPARATUS, TRANSMISSION METHOD, AND TANGIBLE MACHINE-READABLE MEDIUM THEREOF FOR RELAYING DATA SIGNAL IN A MILTI-HOP NETWORK

(75) Inventors: Chih-Chiang Hsieh, Jen-Wu Township (TW); Shiann-Tsong Sheu, Taipei (TW); Hua-Chiang Yin, Guei-Shan Township (TW); Youn-Tai Lee, Yung-Ho City (TW); Kanchei Loa, Taipei (TW); Yung-Ting Lee, Taipei (TW); Yi-Hsueh Tsai, Ban-Chiao (TW); Frank Chee-Da Tsai, Taipei (TW); Heng-Iang Hsu, Taipei (TW)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: INSTITUTE FOR INFORMATION INDUSTRY, Taipei (TW)

(21) Appl. No.: 11/951,123

(22) Filed: Dec. 5, 2007

Related U.S. Application Data
(60) Provisional application No. 60/892,725, filed on Mar. 2, 2007.

(51) Int. Cl. G01R 31/08

(52) U.S. Cl. 370/229

(57) ABSTRACT

An apparatus, a transmission method, and a tangible machine-readable medium thereof for relaying a data signal in a multi-hop relay network are provided, wherein the multi-hop relay network comprising a plurality of relay stations. The apparatus comprises a storage module, a receiving module, and a transmission module. The storage module is configured to store a message of the multi-hop relay network, the message indicating a relation between the apparatus and the relation stations. The receiving module is configured to receive the data signal. The transmission module is configured to transmit the data signal and a first response signal according to the message in response to the data signal, wherein the first response signal relates to a correctness of the data signal.

This application claims the benefit of U.S. Provisional Application Ser. No. 60/892,725 filed on Mar. 2, 2007, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to an apparatus, a transmission method, and a tangible machine-readable medium for relaying a data signal. More specifically, the present invention relates to an apparatus, a transmission method, and a tangible machine-readable medium for relaying a data signal in multi-hop relay network.

2. Descriptions of the Related Art

The hybrid automatic request (HARQ) technique, adopted in the IEEE 802.16 standard, is an advanced data retransmission strategy, which allows performing possible data retransmissions directly at the physical layer instead of the media access control (MAC) layer and/or higher layers. Since the HARQ technique is able to achieve data retransmission without involving mechanisms at the higher layers, the delay caused by data retransmission is significantly reduced. However, the HARQ technique still has some defects in the relay of a multi-hop relay network, and the defects are going to be defined in the IEEE 802.16j standard. Since an HARQ channel can be setup by two approaches (the end-to-end HARQ mechanism and the hop-by-hop HARQ mechanism), the defects of the HARQ are mainly described from the viewpoints of the two approaches.

Please refer to FIG. 1, which illustrates relay of a data signal by a multi-hop relay (MR) system 1 using a conventional end-to-end HARQ mechanism. The MR system 1 comprises a mobile station (MS), two relay stations (RSs, i.e. RS1 and RS2), and a base station (BS). The BS intends to transmit the data signal to the MS. In FIG. 1, the vertical axes indicate the time, Data* indicates the data signal that is corrupted by noise during transmission, and Data indicates the data signal that is successfully transmitted and not corrupted by noise during transmission. It can be understood that, each of the RSs (i.e. RS1 and RS2) should only relay those successfully received/decoded data signals to its successor by using the end-to-end HARQ mechanism. If the RSs receive an erroneously decoded data signal, it reports a negative-acknowledgement (NACK) to the original sender to indicate the request of retransmission. That is, each of the RSs should relay all received acknowledgement (ACK)/NACK to its predecessor. Furthermore, only a destination of the transmission can initiate an ACK. These actions make too much data transfer latency and decrease the performance of whole system 1.

There are other critical issues of the end-to-end HARQ channel. First, in an MR system with centralized scheduling, the pre-schedule bandwidths for multiple links along the relay path may not be fully utilized if there is error occurrence on any link along the relay path. Second, if the HARQ bandwidth allocation is based on on-demand basis, it definitely results in a number of round-trip delays between MS/RS and BS before the data successfully received/decoded at the destination station. Third, the end-to-end HARQ is not suitable for MR system with distributed scheduling.

Please refer to FIG. 2, which illustrates relay of a data signal by an MR system 2 using a conventional hop-by-hop mechanism. The MR system 2 also comprises an MS, two RSs (i.e. RS1 and RS2), and a BS. In FIG. 2, the vertical axes indicate the time, Data* indicates the data signal that is corrupted by noise during transmission, while Data indicates the data signal that is successfully transmitted. By using the hop-by-hop HARQ mechanism, each of the RSs (i.e. RS1 and RS2) should not relay erroneously decoded data signals to its successor unless the data signal is successfully decoded. Furthermore, each of the RSs should not relay received ACK/NACK indications to its predecessor. There are two main defects in a hop-by-hop HARQ mechanism. First, if the relay system 2 adopts centralized scheduling approach, the pre-schedule bandwidths for multiple links along the relay path between BS and MS may not be fully utilized if there is error occurrence on any link along the relay path. Second, if the HARQ bandwidth allocation is based on on-demand manner, it might result in a number of round-trip delays between MS/RS and BS along the relay path.

Accordingly, how to improve the performance of the HARQ in multi-hop relay systems is still an objective for the industry to endeavor.

### SUMMARY OF THE INVENTION

The primary objective of this invention is to provide an apparatus for relaying a data signal in a multi-hop relay network. The apparatus comprises a storage module, a receiving module, a determination module, and a transmission module. The storage module is configured to store a message of the multi-hop relay network, wherein the message indicates a resource allocation of the multi-hop relay network. The receiving module is configured to receive the data signal. The determination module is configured to determine that the data signal is correct. The transmission module is configured to transmit the data signal and to transmit an acknowledgement signal intended to be transmitted to a base station of the multi-hop relay network according to the message.

Another objective of this invention is to provide an apparatus for relaying a data signal in a multi-hop relay network. The apparatus comprises a storage module, a receiving module, a determination module, and a transmission module. The storage module is configured to store a message of the multi-hop relay network, wherein the message indicates a resource allocation of the multi-hop relay network. The receiving module is configured to receive the data signal. The determination module is configured to determine that the data signal is erroneous. The transmission module is configured to transmit the data signal according to the message in response to the determination.

Yet a further objective of this invention is to provide a transmission method for relaying a data signal in a multi-hop relay network. The method comprises the steps of: receiving the data signal; determining that the data signal is correct; transmitting the data signal according to a message, the message indicating a resource allocation of the multi-hop relay network; and transmitting a first acknowledgement signal intended to be transmitted to a base station of the multi-hop relay network according to the message.

Yet a further objective of this invention is to provide a transmission method for relaying a data signal in a multi-hop relay network. The method comprises the steps of: receiving the data signal; determining that the data signal is erroneous; and transmitting the data signal according to the message in response to the determination, the message indicating a resource allocation of the multi-hop relay network.

Yet a further objective of this invention is to provide a tangible machine-readable medium storing a computer program to enable an apparatus to execute a transmission method for relaying a data signal in a multi-hop relay network. The transmission method comprising the steps of: enabling the apparatus to receive the data signal; enabling the apparatus to determine that the data signal is correct; enabling the apparatus to transmit the data signal according to a message, the message indicating a resource allocation of the multi-hop relay network; and enabling the apparatus to transmit a first acknowledgement signal intended to be transmitted to a base station of the multi-hop relay network according to the message.

Yet a further objective of this invention is to provide a tangible machine-readable medium storing a computer program to enable an apparatus to execute a transmission method for relaying a data signal in a multi-hop relay network. The transmission method comprising the steps of: enabling the apparatus to receive the data signal; enabling the apparatus to determine that the data signal is erroneous; and enabling the apparatus to transmit the data signal according to a message in response to the determination, the message indicating a resource allocation of the multi-hop relay network.

The present invention relays a data signal in a multi-hop relay network. In the framework of HARQ, the relay station relays the data signal to successor regardless of the data signal being corrupted by noise during transmission. This will effectively utilize the pre-schedule bandwidths for multiple links to improve the performance of the whole relay system in the multi-hop relay network.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic diagram of relay of a data signal by a multi-hop relay network using a conventional end-to-end HARQ mechanism;

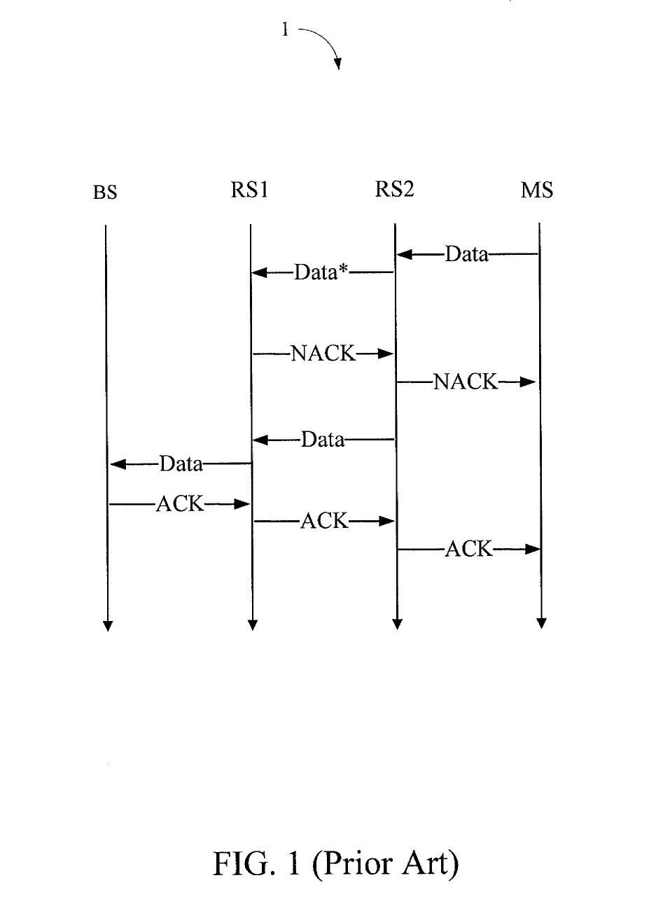

FIG. 2 is a schematic diagram of relay of a day signal by a multi-hop relay network using a conventional hop-by-hop HARQ mechanism;

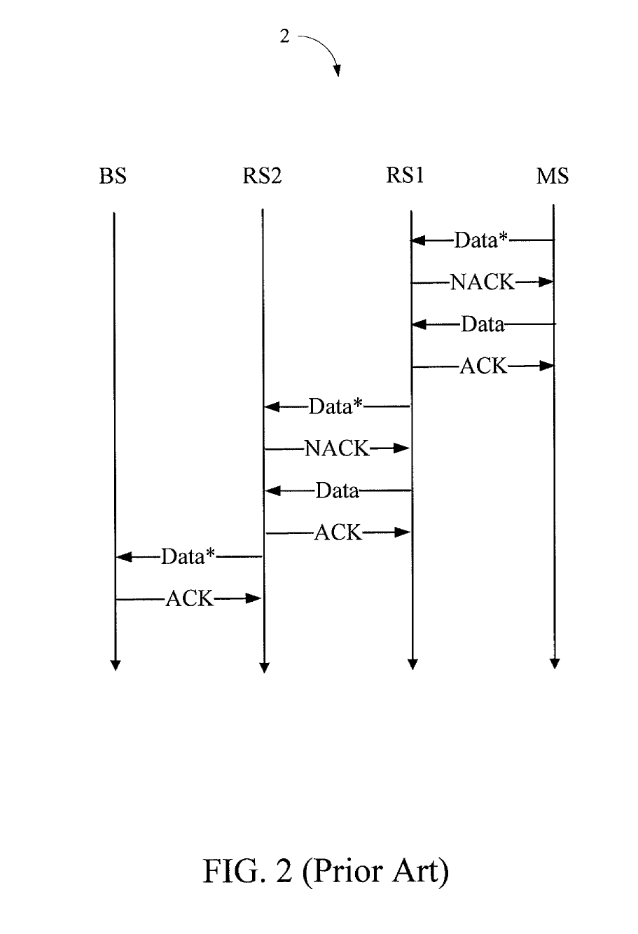

FIG. 3 is a schematic diagram of the first embodiment of the present invention;

FIG. 4 is a schematic diagram of a concrete example of the first embodiment of the present invention; and

FIG. 5 is a flow chart of the second embodiment of the present invention.

### DESCRIPTION OF THE PREFERRED EMBODIMENT

The present invention provides an apparatus, a transmission method, and a tangible machine-readable medium thereof for relaying a data signal in a multi-hop relay network. In the following embodiments, multi-hop relay networks based on the IEEE 802.16j standard are used. However, the scope of the present invention is not limited to the applications based on the IEEE 802.16j standard. The relay operations in a multi-hop relay network based on the IEEE 802.16j standard are well-known by people skilled in the art, and are not repeated again. A multi-hop relay network has two kinds of operations: downlink and uplink operations. In this invention, only the uplink operation in the multi-hop relay network is described. It means that only the relay operations relating to transmitting a data signal from a mobile station (MS) to a base station (BS) are described.

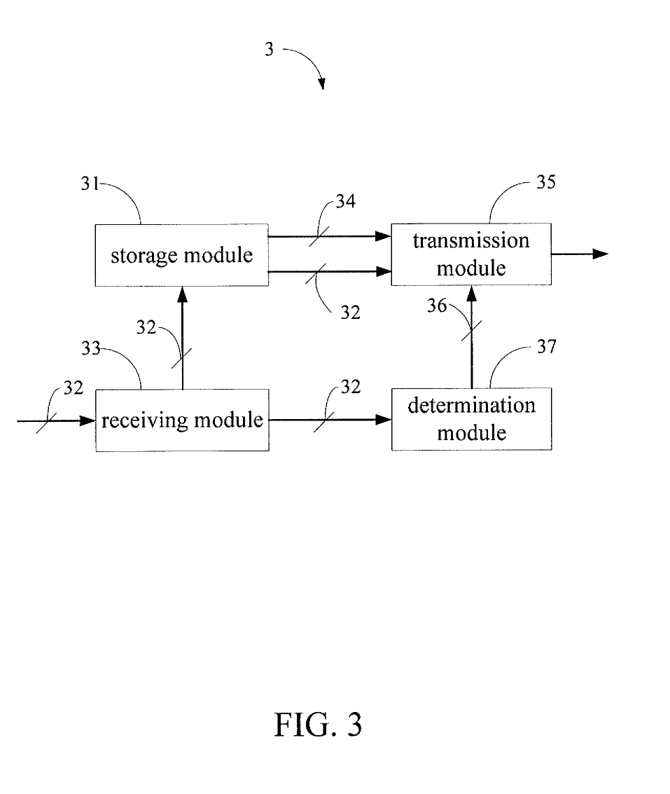

A first embodiment of the present invention is shown in FIG. 3, which shows an apparatus 3 for relaying a data signal 32 from an MS to a BS in a multi-hop relay network. The apparatus 3 can serve as a relay station (RS) in the multi-hop relay network. The apparatus 3 comprises a storage module 31, a receiving module 33, a transmission module 35, and a determination module 37. The storage module 31 is configured to store a message 34 of the multi-hop relay network, wherein the message 34 is configured to indicate a resource allocation of the multi-hop relay network.

The receiving module 33 is configured to receive the data signal 32. Then, the data signal 32 is stored in the storage module 31. The data signal 32 is also sent to the determination module 37 so that the determination module 37 can determine whether the data signal 32 is correct or not. That is, the determination module 37 is configured to determine whether the data signal 32 is corrupted by noise during transmission. If the determination module 37 determines that the data signal is correct, it generates a first acknowledgement signal 36 intended to be transmitted to the BS in the multi-hop relay network. The transmission module 35 is then configured to retrieve the data signal 32 from the storage module 31 and then transmit the data signal 32 and the first acknowledgement signal 36 to the BS according to the message 34. The multi-hop relay network may comprise other relay stations, and the transmission module 35 of the apparatus 3 can know its successor (such as the RS/MS) and/or predecessor (such as the BS/RS) from the message 34. So, the transmission module 35 of the apparatus 3 transmits the data signal 32 and the first acknowledgement signal 36 to its successor on the routing path to the BS.

If the receiving module 33 receives the data signal 32 from another RS but not directly from the MS, the receiving module 33 is further configured to receive a second acknowledgement signal from the another RS, and then the transmission module 35 is further configured to transmit the second acknowledgement signal according to the message 34 to its successor.

If the determination module 37 determines that the data signal 32 is erroneous, the transmission module 35 is still configured to retrieve the data signal 32 from the storage module 31 and then transmit the data signal 32 according to the message 34. The receiving module 33 is further configured to receive a negative-acknowledgement signal intended to be transmitted to the BS, and the transmission module 35 is further configured to transmit the negative-acknowledgement signal according to the message 34. Particularly, the negative-acknowledgement signal intended to be transmitted to the MS of the multi-hop relay network is generated by the BS. It means that the apparatus 3 can relay the negative-acknowledgement signal in the multi-hop relay network.

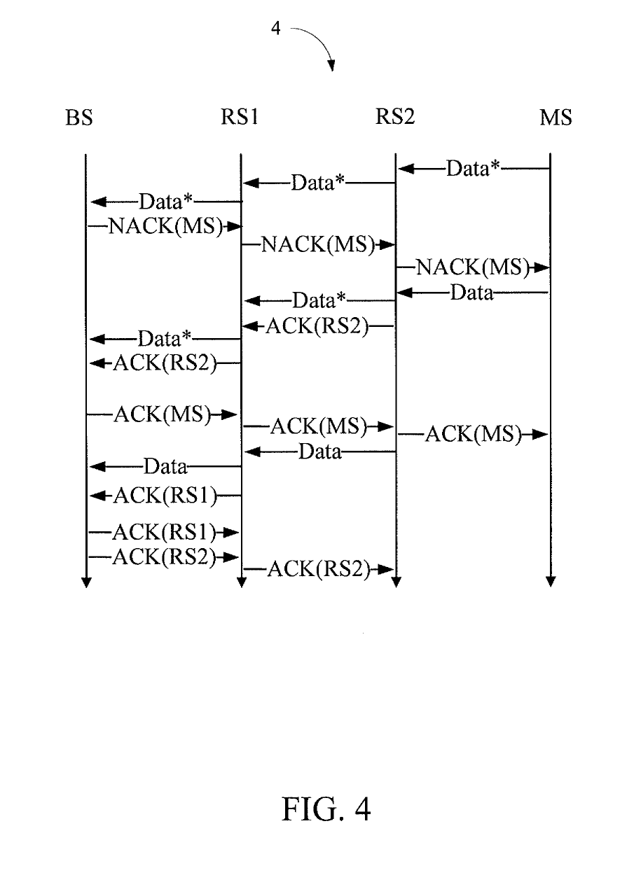

As mentioned, the apparatus 3 can be a relay station in a multi-hop relay network. Please refer to FIG. 4 for a concrete example, which shows an uplink transmission of a data signal in a multi-hop relay system 4. The multi-hop relay system 4 comprises an MS, two RSs (RS1 and RS2), and a BS, wherein each of the RS1 and the RS2 is the apparatus 3 of this embodiment. In FIG. 4, the vertical axes indicate the time, Data* indicates the data signal that is corrupted by noise during transmission, and Data indicates the data signal that is successfully transmitted.

First, the data signal intended to be transmitted from the MS to the BS is corrupted by noise during transmission, which can be seen from the Data* symbols. Since the BS receives a corrupted data signal Data*, it sends an NACK(MS) to MS. The NACK(MS) is relayed by the RS1 and the RS2 to the MS. The process means that the RSs relay the data signal regardless of the correctness of the data signal. If the data signal is corrupted, the RSs further relay the NACK signal from the BS.

Then, the RS2 receives the data signal again, and it correctly receives the data signal this time. The RS2 then decodes the retransmitted data signal, and then send an ACK(RS2) to the BS to inform the BS that the RS2 has the complete data signal. The RS2 relays the data signal to the RS1.

From FIG. 4, it can be seen that the transmission between the RS1 and RS2 appears erroneous. That is, although the RS2 correctly receives the data signal, the RS1 does not receive the correct data signal from the RS. The RS1 still relays the corrupted data signal to the BS. After the BS still receives the corrupted data signal, it requests the RS2 to retransmit the complement data signal instead of requesting the MS. The BS can request RS2 to retransmit the data because the BS received the ACK(RS2). It means that as long as one RS in multi-hop relay system 4 receives and decodes the data signal successful, the MS will not be asked to retransmit the data signal. The retransmission request will operate between the RSs and BS until the BS received and decoded the data signal successfully.

According to the above configurations, the present invention provides an apparatus to relay a data signal regardless of the correctness of the data signal. This can effectively utilize the pre-schedule bandwidths for multiple links to improve the performance of the multi-hop relay system in the uplink transmission.

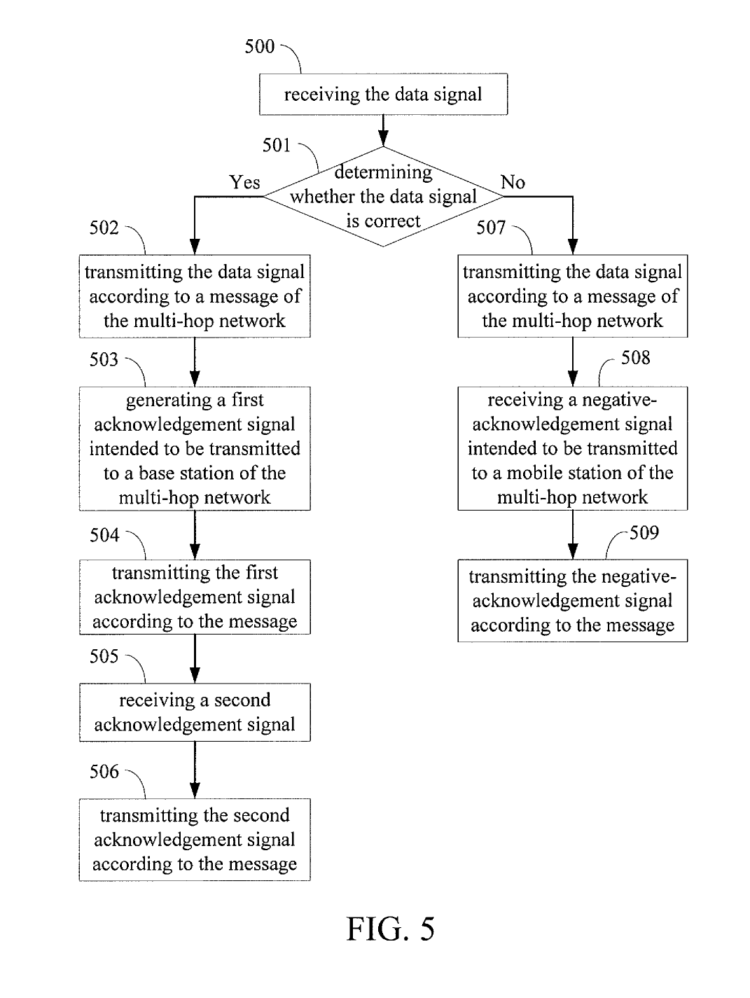

A second embodiment of the present invention is shown in FIG. 5, which shows a flow chart of a transmission method for relaying a data signal in a multi-hop relay network, wherein the multi-hop relay network comprises a plurality of relay stations. First, step 500 is executed to receive the data signal. Then, Step 501 is executed to determine whether the data signal is correct. If so, step 502 is executed to transmit the data signal according to a message of the multi-hop relay network, wherein the message indicates a resource allocation of the multi-hop relay network. Then, step 503 is then executed to generate a first acknowledgement signal intended to be transmitted to a BS of the multi-hop relay network. Then, step 504 is executed to transmit the first acknowledgement signal according to the message. Step 505 is executed to receive a second acknowledgement signal. Then, step 506 is executed to transmit the second acknowledgement signal according to the message.

If the step 501 determines that the signal is not correct, step 507 is executed to transmit the data signal according to the message of the multi-hop relay network. Then, step 508 is executed to receive a negative-acknowledgement signal intended to be transmitted to an MS of the multi-hop relay network. Finally, step 509 is executed to transmit the negative-acknowledgement signal according to the message.

In addition to the aforementioned steps, the second embodiment is able to execute all the functions and operations described in the first embodiment.

Each of the aforementioned methods can use a tangible machine-readable medium for storing a computer program to execute the aforementioned steps. The tangible machine-readable medium can be a floppy disk, a hard disk, an optical disc, a flash disk, a tape, a database accessible from a network or a storage medium with the same functionality that can be easily thought by people skilled in the art.

According to the aforementioned descriptions, the present invention provides a new approach to relay a data signal from its predecessor to its successor regardless of the correctness of the data signal. This will effectively utilize the pre-schedule bandwidths to improve the performance of the relay system in the multi-hop relay network. The present invention can be utilized in multi-hop relay network, such as those based on the IEEE 802.16j standard.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. An apparatus for relaying a data signal in a multi-hop relay network, comprising:
a storage module being configured to store a message of the multi-hop relay network, the message indicating a resource allocation of the multi-hop relay network;
a receiving module being configured to receive the data signal;
a determination module being configured to determine that the data signal is correct; and
a transmission module being configured to transmit the data signal and to transmit an first acknowledgement signal intended to be transmitted to a base station of the multi-hop relay network according to the message.

2. The apparatus of claim 1, wherein the receiving module is further configured to receive a second acknowledgement signal and the transmission module is further configured to transmit the second acknowledgement signal according to the message.

3. An apparatus for relaying a data signal in a multi-hop relay network, comprising:
a storage module being configured to store a message of the multi-hop relay network, the message indicating a resource allocation of the multi-hop relay network;
a receiving module being configured to receive the data signal;
a determination module being configured to determine that the data signal is erroneous; and
a transmission module being configured to transmit the data signal according to the message in response to the determination.

4. The apparatus of claim 3, wherein the receiving module is further configured to receive a negative-acknowledgement signal intended to be transmitted to a mobile station of the multi-hop relay network and the transmission module is further configured to transmit the negative-acknowledgement signal according to the message.

5. A transmission method for relaying a data signal in a multi-hop relay network, comprising the steps of:
receiving the data signal;
determining that the data signal is correct;
transmitting the data signal according to the message, the message indicating a resource allocation of the multi-hop relay network; and
transmitting a first acknowledgement signal intended to be transmitted to a base station of the multi-hop relay network according to the message.

6. The transmission method of claim 5, further comprising the steps of:
receiving a second acknowledgement signal; and
transmitting the second acknowledgement signal according to the message.

7. A transmission method for relaying a data signal in a multi-hop relay network, comprising the steps of:
receiving the data signal;
determining that the data signal is erroneous; and
transmitting the data signal according to a message in response to the determining step, the message indicating a resource allocation of the multi-hop relay network.

8. The transmission method of claim 7, further comprising the steps of:
receiving a negative-acknowledgement signal intended to be transmitted to a mobile station of the multi-hop relay network; and
transmitting the negative-acknowledgement signal according to the message.

9. A tangible machine-readable medium storing a computer program to enable an apparatus to execute a transmission method for relaying a data signal in a multi-hop relay network, the transmission method comprising the steps of:
enabling the apparatus to receive the data signal;
enabling the apparatus to determine that the data signal is correct;
enabling the apparatus to transmit the data signal according to a message, the message indicating a resource allocation of the multi-hop relay network; and
enabling the apparatus to transmit a first acknowledgement signal intended to be transmitted to a base station of the multi-hop relay network according to the message.

10. The tangible machine-readable medium of claim 9, wherein the transmission method further comprises the steps of:
enabling the apparatus to receive a second acknowledgement signal; and
enabling the apparatus to transmit the second acknowledgement signal according to the message.

11. A tangible machine-readable medium storing a computer program to enable an apparatus to execute a transmission method for relaying a data signal in a multi-hop relay network, the transmission method comprising the steps of:
enabling the apparatus to receive the data signal;
enabling the apparatus to determine that the data signal is erroneous; and
enabling the apparatus to transmit the data signal according to a message in response to the determination, the message indicating a resource allocation of the multi-hop relay network.

12. The tangible machine-readable medium of claim 11, wherein the transmission method further comprises the steps of:
enabling the apparatus to receive a negative-acknowledgement signal intended to be transmitted to a mobile station of the multi-hop relay network; and
enabling the apparatus to transmit the negative-acknowledgement signal according to the message.
